(19) United States
(12) Patent Application Publication
(10) Pub. No.: US 2025/0109486 A1
(43) Pub. Date: Apr. 3, 2025

(54) CALIBRATION ASSEMBLY FOR A LITHIUM DEPOSITION PROCESS, LITHIUM DEPOSITION APPARATUS, AND METHOD OF DETERMINING A LITHIUM DEPOSITION RATE IN A LITHIUM DEPOSITION PROCESS

(71) Applicants: Sebastian FRANKE, Hanau (DE); Daniel STOCK, Gießen (DE); Tobias STOLLEY, Oberursel (DE); Applied Materials, Inc., Santa Clara, CA (US)

(72) Inventors: Sebastian FRANKE, Hanau (DE); Daniel STOCK, Gießen (DE); Tobias STOLLEY, Oberursel (DE)

(21) Appl. No.: 18/832,126

(22) PCT Filed: Feb. 11, 2022
(86) PCT No.: PCT/EP2022/053391

§ 371 Date: Jul. 23, 2024

(51) Int. Cl. C23C 14/54; C23C 14/14; C23C 14/24; G01B 17/02

(52) U.S. Cl. CPC C23C 14/54; C23C 14/14; C23C 14/24; G01B 17/025

(57) ABSTRACT

A calibration assembly for a lithium deposition process is described. The calibration assembly includes a carrier, and a piezoelectric resonator coupled to the carrier. The calibration assembly is configured for being processed in the lithium deposition process. The lithium deposition process includes a passivation. The piezoelectric resonator is configured for being electrically connected to a driver for determining a resonant frequency of the piezoelectric resonator. The resonant frequency is indicative of a thickness of a lithium film deposited on the piezoelectric resonator in the lithium deposition process. A change of the resonant frequency over time is indicative of the passivation of the lithium film.

### TECHNICAL FIELD

Embodiments of the present disclosure generally relate to a process of lithium deposition on a substrate, particularly the measurement of a lithium deposition rate and a calibration of the lithium deposition process. Embodiments of the present disclosure particularly relate to the use of a piezoelectric resonator in a calibration assembly, specifically a resonator of a quartz crystal microbalance, for measuring a thickness of a lithium film deposited in the deposition process.

### BACKGROUND

Metal vapor deposition processes, such as physical vapor deposition (PVD) are known in the art. A metallic material is evaporated in a deposition apparatus and directed towards a substrate to form a film, layer or coating on the substrate. Beneficially, the deposition process may be controlled to achieve a uniform and consistent material deposition and/or layer thickness.

For controlling the deposition rate, a layer thickness measuring device may be utilized for measuring the layer thickness of the deposited layer. The measured layer thickness may then be utilized for adjusting a process parameter, e.g. to achieve a desired layer thickness. For example, a drop gauge may be utilized to determine a difference in thickness of a substrate before and after a deposition process, the difference corresponding to the layer thickness. However, this may be inaccurate.

Lithium vapor deposition is an attractive method for forming layers or coatings of lithium on a substrate. Processed substrates may, for example, serve as components of energy storage devices. In a typical process, metallic lithium is thermally evaporated in a PVD process, typically performed in a lithium deposition apparatus, and subsequently deposited on the substrate by exposing the substrate to the lithium metal vapor.

Accurate monitoring of the layer thickness may not be possible with known deposition rate measurement devices within the lithium deposition apparatus due to the high temperature and reactivity of lithium metal vapor, which may negatively affect or even destroy components of the thickness measurement device. Furthermore, for known solutions, it is typically not possible to monitor reactions, such as passivation reactions, of the deposited layer, which may occur after the deposition process or even outside the deposition apparatus.

In view of the above, it is beneficial to provide a calibration assembly, a lithium deposition apparatus and a method of determining a lithium deposition rate that is suitable for determining a layer thickness of a layer deposited in a lithium deposition process.

### SUMMARY

According to one embodiment, a calibration assembly for a lithium deposition process is described. The calibration assembly includes a carrier, and a piezoelectric resonator coupled to the carrier. The calibration assembly is configured for being processed in the lithium deposition process. The lithium deposition process includes a passivation. The piezoelectric resonator is configured for being electrically connected to a driver for determining a resonant frequency of the piezoelectric resonator. The resonant frequency is indicative of a thickness of a lithium film deposited on the piezoelectric resonator in the lithium deposition process. A change of the resonant frequency over time is indicative of the passivation of the lithium film.

According to one embodiment, a lithium deposition apparatus is described. The lithium deposition apparatus includes a calibration assembly according to embodiments described herein. The lithium deposition apparatus further includes a processing chamber. The processing chamber includes a lithium evaporation device, and a transfer chamber connected to the processing chamber. The lithium deposition apparatus is configured for processing the calibration assembly in the processing chamber, transferring the calibration assembly from the processing chamber to the transfer chamber, passivating a lithium film deposited on the calibration assembly during processing in the transfer chamber, and electrically connecting the piezoelectric resonator to the driver with a connector, the connector being provided in a testing environment.

According to one embodiment, a method of determining a lithium deposition rate in a lithium deposition process is described. The method includes providing a calibration assembly including a carrier and a piezoelectric resonator coupled to the carrier, and processing the calibration assembly as a substrate in a processing chamber of the lithium deposition process. The piezoelectric resonator is disconnected from a driver during processing. The method further includes removing the calibration assembly from the processing chamber, electrically connecting the piezoelectric resonator to a driver, and determining a resonant frequency of the piezoelectric resonator. The resonant frequency is indicative of a thickness of a lithium film deposited on the piezoelectric resonator in the lithium deposition process. The method further includes determining the lithium deposition rate from the thickness of the lithium film.

According to one embodiment, a method of characterizing a lithium deposition process is described. The method includes providing a calibration assembly comprising a carrier and a piezoelectric resonator coupled to the carrier, processing the calibration assembly as a substrate in a processing chamber of the lithium deposition process, forming a passivation layer on the lithium film deposited on the piezoelectric resonator to form a passivated lithium film, removing the calibration assembly from the processing chamber, electrically connecting the piezoelectric resonator to a driver, and determining a first resonant frequency of the piezoelectric resonator. The first resonant frequency is indicative of a thickness of a lithium film deposited on the piezoelectric resonator in the lithium deposition process. The method further includes determining a second resonant frequency. Determining the second resonant frequency includes monitoring a change of the second resonant frequency of the piezoelectric resonator over time. A change of the second resonant frequency over time is indicative of the chemical stability of the passivated lithium film.

### BRIEF DESCRIPTION OF THE DRAWINGS

So that the manner in which the above recited features can be understood in detail, a more particular description, briefly summarized above, may be had by reference to embodiments. The accompanying drawings relate to embodiments and are described in the following:

FIG. 1A schematically shows a calibration assembly according to an embodiment in a plan view;

FIG. 1B schematically shows a calibration assembly according to an embodiment in a side view;

FIG. 2 schematically shows a piezoelectric resonator according to embodiments electrically connected to a driver;

FIG. 3 schematically shows a lithium deposition apparatus according to embodiments in a side view;

FIG. 4 shows a method of determining a lithium deposition rate according to embodiments; and

FIG. 5 shows a graph of a change in resonant frequency of a passivated lithium film and a non-passivated lithium film.

### DETAILED DESCRIPTION OF EMBODIMENTS

Reference will now be made in detail to the various embodiments, one or more examples of which are illustrated in the figures. Within the following description of the drawings, the same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

According to an aspect, a piezoelectric resonator is described. The piezoelectric resonator may be a crystal oscillator, such as a quartz crystal oscillator. The piezoelectric resonator may be a polycrystalline and/or ceramic oscillator.

According to an aspect, the piezoelectric resonator may be a resonator for use with a microbalance, particularly a quartz crystal microbalance. The piezoelectric resonator may include at least one essentially flat surface, such as two essentially flat surfaces, such as two opposed essentially flat surfaces. The piezoelectric resonator may be essentially flat, e.g. disc-shaped, the flat surfaces being the opposing surfaces and/or faces of the disc, however, the piezoelectric resonator is not limited to any particular shape. The piezoelectric resonator may have one or more electrodes formed on the at least one essentially flat surface, such as two electrodes formed on the two essentially flat surfaces, particularly for providing a voltage, such as an alternating voltage, to a portion of the piezoelectric resonator, particularly to cause the piezoelectric resonator to oscillate. The piezoelectric resonator may form a resonator of a microbalance, particularly a quartz crystal microbalance, when electrically connected to a driver. The driver may be a driver of a microbalance, particularly a quartz crystal microbalance (QCM). The piezoelectric resonator may comprise a quartz crystal, particularly an AT-cut quartz crystal or an RC-cut quartz crystal. The quartz crystal may be essentially disc-shaped and have, on each face of the disc, an electrode formed thereon. The piezoelectric resonator may be a QCM chip.

According to an aspect, reference is made herein to a lithium film. A lithium film may be a layer of lithium, and may likewise be understood as a layer. The lithium film or layer may be a continuous layer or film. A lithium layer formed, at least initially, of a number of micro-islands, may also be considered a lithium film.

According to an aspect, the piezoelectric resonator may have a resonant frequency. The resonant frequency of the piezoelectric resonator may be affected according to a mass of a material deposited onto one or more of the at least one essentially flat surface. Particularly, depositing a material onto a surface (i.e. the at least one essentially flat surface) of the piezoelectric resonator may result in an increase in mass on the surface and a decrease in the resonant frequency of the piezoelectric resonator. The resonant frequency, particularly a change and/or decrease of the resonant frequency, may be indicative of a layer thickness of a lithium film deposited onto a surface of the piezoelectric resonator.

According to an aspect, a layer thickness of a lithium film deposited onto a surface of the piezoelectric resonator may be, at least approximately and/or within an error margin, calculated according to the following formula. The given values F_{q} and Z_{q} may be specific for each type of piezoelectric resonator, and are given here as an example. A lithium film deposited on the piezoelectric resonator may have a density p of 0.53 gcm⁻³. According to the microstructure of the deposited lithium film, the density p may be lower, as explained herein with reference to the effect of island formation.

$${T}_{f} = \frac{{Z}_{q} \times {10}^{4}}{2 π zp} \{ ( \frac{1}{{F}_{co}} ) A Tan ( z Tan ( \frac{π {F}_{co}}{{F}_{q}} ) ) - ( \frac{1}{{F}_{c}} ) A Tan ( z Tan ( \frac{π {F}_{c}}{{F}_{q}} ) ) \}$$

where:
T_{f}=thickness of deposited film (kÅ)
F_{co}=starting frequency of the sensor crystal (Hz)
F_{c}=Final frequency of the sensor crystal (Hz)
F_{q}=Nominal blank frequency=6045000 (Hz)
z=Z-Ratio of deposited film material
Z_{q}=Specific acoustic impedance of quartz=8765000 (MKS units)
p=density of deposited film (g/cc)

According to an aspect, a calibration assembly is described. In the context of the disclosure, the calibration assembly may be described as being processed as a substrate in a lithium deposition process or apparatus. This is to be understood as the calibration assembly being exposed to the same conditions as a substrate and/or in place of a substrate, and should not be understood as a processing of the calibration assembly resulting in a processed substrate having the same properties as a substrate that is not a calibration assembly. The calibration assembly may be processed, e.g. in place of a substrate assembly including a substrate and a substrate carrier, e.g. by having essentially the same dimensions as the substrate assembly.

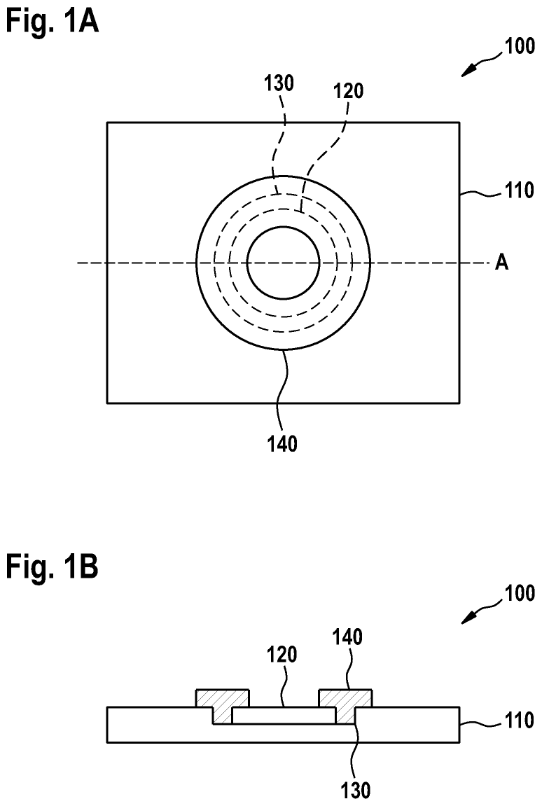

FIG. 1 shows a calibration assembly 100 for a lithium deposition process according to an embodiment, FIG. 1A showing a plan view and FIG. 1B showing a cutaway side view along the axis A. Some elements of the calibration assembly 100 may not be drawn to scale.

The calibration assembly 100 includes a carrier 110. The carrier 110 may be made essentially of a material suitable for being exposed to metallic lithium vapor, such as a metal. For example, but not limited thereto, the carrier may comprise, and/or be made of copper, such as a copper-based alloy, steel, particularly stainless steel, nickel, nickel alloys, and/or aluminum.

As shown in FIG. 1B, according to embodiments, the carrier 110 includes an indentation 130 for receiving the piezoelectric resonator 120. The carrier 110 according to the embodiment further includes a fastener 140 for coupling, particularly mechanically coupling, the piezoelectric resonator 120 to the carrier. In the embodiment, the fastener 140 may be a nut that threads into sidewalls of the indentation 130. According to embodiments, the fastener 140 may be a clamp, a clip, a lock ring, a mounting bracket or any other mechanical structure for reversibly securing the piezoelectric resonator 120 within the indentation. As shown in FIG. 1A, the fastener 140 includes an opening exposing a portion of a surface of the piezoelectric resonator 120 such that a lithium film may be deposited on the exposed surface. The fastener may be made essentially of a metal, e.g. the fastener may comprise, and/or be made of copper, such as a copper-based alloy, steel, particularly stainless steel, nickel, nickel alloys, and/or aluminum.

According to embodiments, a gap may be provided between the outer circumference of the piezoelectric resonator 120 and the fastener 140.

According to embodiments, the calibration assembly 100 may include further mounting elements, such as elastic elements, for evenly distributing contacting forces across the piezoelectric resonator 120, particularly to avoid a cracking of the piezoelectric resonator 120 due to mechanical stress during assembly of the calibration assembly 100 or processing. The elastic elements may include, but are not limited to, buffers, O-rings, sleeves, bushings, elastic plates or the like. The elastic elements may be provided between the outer circumference of the piezoelectric resonator 120, and/or any of the flat surfaces of the piezoelectric resonator 120 contacting the carrier 110 and/or the fastener 140. The elastic element may comprise a polymer, particularly an inert polymer and/or a temperature resistant polymer, such as polytetrafluoroethylene (PTFE), polyether ether ketone (PEEK), and/or nitrile rubber.

According to embodiments, the carrier 110 may, instead of the indentation 130, have a through hole and a ridge provided on an edge of the through hole. A bushing, such as a polymer bushing, may be inserted into the through hole, a first edge of the bushing resting on the ridge. The piezoelectric resonator 120 may rest, within the through-hole, on a second edge of the bushing opposing the first edge. The fastener 140 may couple the piezoelectric resonator to the carrier by pressing the piezoelectric resonator against the second edge of the bushing.

According to embodiments, the piezoelectric resonator 120 is removably coupled to the carrier 110, and removable from the carrier 110, particularly before or after the lithium deposition process, e.g. to determine a resonant frequency of the piezoelectric resonator 120 before and after the lithium deposition process. The piezoelectric resonator 120 may be coupled to the carrier 110 to form a calibration assembly 100. The calibration assembly 100 may be processed in a lithium deposition process. The calibration assembly 100 may, after processing, be disassembled by removing the piezoelectric resonator 120 from the calibration assembly 100.

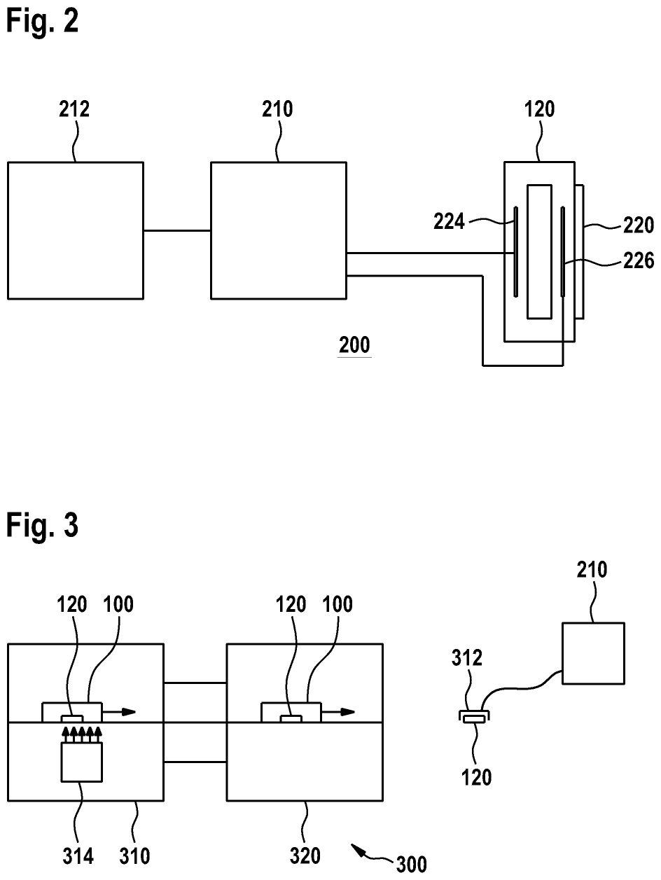

Referring now to FIG. 2, a piezoelectric resonator 120 is shown in a measuring configuration 200 according to an embodiment. In the measuring configuration 200, the piezoelectric resonator 120 may be removed from the carrier 110 and, for example, connected to a measuring instrument, such as a connector of a QCM system and/or such as the connector 312 shown in FIG. 3. Accordingly, the piezoelectric resonator 120 may be insertable into a connector (not shown) of the driver 210 for electrically connecting the piezoelectric resonator 120 to the driver 210. The measuring instrument may include a driver 210. The driver 210 may be a measuring instrument, or included in the measuring instrument. The driver may be connected to an evaluation device 212. The evaluation device 212 may be included in the driver 210 and/or the measuring instrument. The evaluation device 212 may, for example, be a frequency analyzer, particularly for determining a frequency of an oscillator including the piezoelectric resonator 120, particularly a resonant frequency of the piezoelectric resonator 120. As shown in FIG. 2, the electrodes 224, 226 of the piezoelectric resonator 120 are electrically connected to the driver in the measuring configuration 200. The driver 210 is configured for providing a voltage, particularly an alternating voltage, to the electrodes 224, 226. The driver may be configured for tuning the alternating voltage to the resonant frequency of the piezoelectric resonator 120. Alternatively, the driver may be configured for driving the piezoelectric resonator 120 at a predetermined frequency, and perform an impedance analysis for a frequency range. Further modes of operation of the driver 210, such as QCM-I, ring-down or QCM-D may be employed. In the measuring configuration 200, the driver 210, together with the piezoelectric resonator 120, may form an oscillator oscillating at a resonant frequency, or an overtone of the resonant frequency, of the piezoelectric resonator 120. The driver 210, particularly in combination with the evaluation device 212, may be configured for determining the resonant frequency, or an overtone of the resonant frequency, of the piezoelectric resonator 120.

As shown in FIG. 2, particularly after being processed in a lithium deposition process, the piezoelectric resonator 120 may have a lithium film 220 deposited on a surface of the piezoelectric resonator 120. It should be noted that, although empty spaces have been drawn on each side of the electrode 226 in FIG. 2 for clarity, the lithium film may be formed directly on the electrode 226 and/or even a crystalline, polycrystalline and/or ceramic portion of the piezoelectric resonator 120.

According to embodiments, the resonant frequency is indicative of a thickness of the lithium film 220 deposited on the piezoelectric resonator 120 in the lithium deposition process. Particularly, a thickness of the lithium film 220 may be derived from the difference in the resonant frequency of the piezoelectric resonator 120 before and after depositing the lithium film 220.

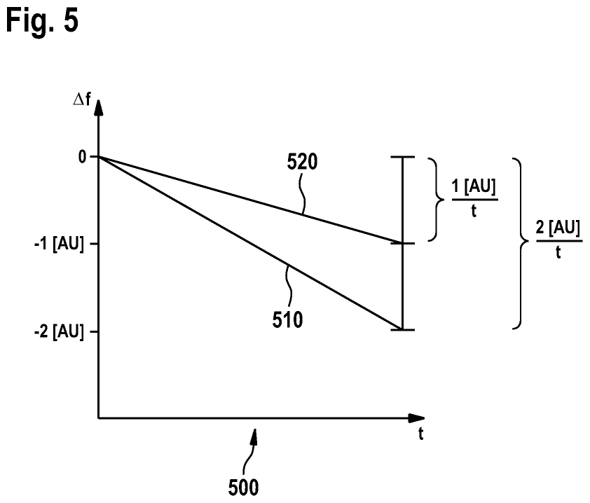

According to embodiments, a change of the resonant frequency over time is indicative of the passivation of the lithium film, as will be explained herein in further detail with reference to FIG. 3 and FIG. 5.

According to embodiments, the piezoelectric resonator 120 comprises an inert metal electrode on a face of the piezoelectric resonator 120. The inert metal electrode may particularly be an electrode 226 configured for having a lithium film deposited thereon. Inert, in the context of the disclosure, may be understood as non-reactive with lithium metal during and after having a lithium film deposited on the electrode, and may particularly be understood as the inert metal electrode being non-reactive with lithium vapor, lithium metal and/or passivated lithium.

According to embodiments, the calibration assembly 100, particularly including the carrier 110 and the piezoelectric resonator 120, is inert when processed in a lithium vapor atmosphere, the lithium vapor atmosphere being generated by evaporating lithium, particularly lithium metal, at 500° C. or more under vacuum. The lithium vapor atmosphere may be generated by evaporating lithium metal at more than 500° C., such as more than 600° C., or even more than 700° C. The lithium metal may be thermally evaporated, e.g. in a crucible and/or an evaporator transferring thermal energy to the lithium through contact, i.e. the evaporation process may be a process not including the use of other energy types such as photon or particle radiation, and/or the use of lithium compounds not including metallic lithium. Vacuum, in the context of the disclosure, may be a pressure of less than 10⁻³ hPa, such as a pressure of less than 10⁻⁴ hPa or less than 10⁻⁵ hPa, e.g. a pressure in the range of 10⁻⁶ hPa to 10⁻⁷ hPa.

It was experimentally observed that an electrode 226 formed of aluminum and aluminum-based alloys, as well as molybdenum and molybdenum-based alloys, particularly molybdenum/aluminum, would degrade during or after having a lithium film deposited thereon at least once. It was further observed that electrodes comprising noble metals, such as platinum group metals, particularly silver or gold are stable under the conditions described herein. Accordingly, the electrode 226 may beneficially comprise or be formed of a noble metal and/or a platinum group metal, particularly silver or gold.

It was further experimentally observed that an electrode 226 formed of gold may result in the lithium film, when deposited under the conditions described herein, to initially grow on the gold surface in the form of micrometer-sized islands. Accordingly, lithium films having a layer thickness of less than 1.5 micrometers may be less dense than a bulk lithium film, and a measurement of a lithium film thickness may be inaccurate unless a lithium film having a thickness of 1.5 micrometers or more is deposited onto the gold electrode 226. Consequently, an electrode 226 formed of gold may be particularly suitable for measuring a lithium deposition resulting in a film thickness of more than 1.5 micrometers. Furthermore, an electrode 226 formed of gold may be particularly suitable for measuring a lithium deposition resulting in a film thickness of less than 1.5 micrometers in cases where a lithium film having a thickness of more than 1.5 micrometers was previously deposited on the gold electrode 226, i.e. where the gold electrode was pre-conditioned. An electrode 226 formed of silver did not show the island growth behavior and may therefore be particularly suitable, even for measuring lithium films having a thickness of less than 1.5 micrometers, particularly without requiring a pre-conditioning of the silver electrode 226.

According to embodiments, additionally or alternatively, a non-preconditioned electrode 226 formed of gold may be utilized for accurately measuring a lithium deposition resulting in a film thickness of less than 1.5 micrometers, e.g. by utilizing a calibration factor and/or calibration curve, the calibration factor and/or calibration curve e.g. correlating the observed lithium film thickness with the actual density of the micrometer-sized island film. For example, a calibration curve may include and/or allow to calculate, for a plurality of observed film thicknesses, a density value p which is lower than the density value p of a bulk lithium film, and the observed film thickness may be corrected based on the calibration curve.

According to embodiments, the piezoelectric resonator 120 may be suitable for determining an increase in lithium film thickness of less than 1 micrometer, particularly less than 500 nanometers, particularly less than 300 nanometers or even less than 200 nanometers. For example, the piezoelectric resonator 120 may be particularly suitable for determining the thickness of a deposited lithium film having a thickness between 100 nanometers and 500 nanometers.

According to embodiments, as shown in FIGS. 1A and 1B, the carrier 110 may include an opening exposing the inert metal electrode 226, directly or indirectly, to a lithium deposition source of the lithium deposition process for having a lithium film 220 deposited on the inert metal electrode 226 when processed in the lithium deposition process. The opening may have essentially the same inner diameter as the diameter of the electrode 226, or an inner diameter within the range of ±10% of the electrode 226. Accordingly, the piezoelectric resonator 120 may be configured for being inserted into the carrier such that the inert metal electrode 226 is exposed, e.g. through an opening in the carrier and/or the fastener, for having a lithium film 220 deposited thereon.

Referring now to FIG. 3, a lithium deposition apparatus 300 according to an embodiment is shown schematically. The lithium deposition apparatus 300 includes a calibration assembly, such as the calibration assembly 100 according to embodiments described herein, a processing chamber 310 and a transfer chamber 320. The processing chamber 310 has a lithium evaporation device 314, particularly for generating lithium vapor as described herein e.g. with reference to the lithium deposition process. The processing chamber 310 is configured for processing the calibration assembly 100, particularly by exposing the calibration assembly 100, e.g. in place of a substrate and/or as a substrate, to a lithium vapor atmosphere according to embodiments described herein. Accordingly, the processing chamber 310 may include, or have fluidly connected thereto, a vacuum pump for providing a vacuum, according to the vacuum described with reference to the lithium vapor atmosphere. The transfer chamber 320 is connected to the processing chamber 310 for allowing a transfer of the calibration assembly 100 from the processing chamber 310 to the transfer chamber 320. Likewise, a substrate processed in the processing chamber 310 may be transferred from the processing chamber 310 to the transfer chamber 320.

According to embodiments, the transfer chamber 320 is configured for passivating a lithium layer deposited on the calibration assembly during processing, particularly a lithium layer deposited in the processing chamber 310.

According to an aspect, lithium metal is known to spontaneously form a native passivation layer under e.g. dry atmospheric conditions. A native passivation layer may include several lithium species, such as carbonates, oxides, hydroxides, or even elemental carbon, carbides and nitrides. Some of these lithium species may be undesirable in the intended use of the substrate. Accordingly, it may be beneficial to selectively promote the generation of certain passive lithium species while avoiding the generation of undesired species by exposing the freshly deposited lithium film to a controlled atmosphere. Beneficially, the calibration assembly 100 may be utilized for evaluating a passivation, and for calibrating a passivation operation according to the evaluation.

According to embodiments, the transfer chamber 320 may be configured for passivating the lithium layer by providing a controlled atmosphere including carbon dioxide to promote the generation of a passivation layer including a reaction product of metallic lithium and carbon dioxide, such as lithium carbonate. The controlled atmosphere may be free of other gases having a reactivity with lithium, particularly nitrogen, water vapor and/or oxygen. The controlled atmosphere may include an inert gas, such as a noble gas, such as argon. The controlled atmosphere may provide carbon dioxide gas at a controlled pressure or a controlled partial pressure, such as, for example, 300 to 700 mbar, such as approximately 500 mbar. The transfer chamber 320 may be configured for exposing a substrate or the calibration assembly to the controlled atmosphere for a predetermined time. Accordingly, the transfer chamber may include one or more gas inlets, a pressure controller, a temperature controller and/or a timer.

As shown in FIG. 3, the lithium deposition apparatus 300 is configured for electrically connecting the piezoelectric resonator 120 to a driver 210 with a connector 312, the connector 312 being provided in a testing environment. Electrically connecting the piezoelectric resonator 120 to the connector 312 may allow determining a resonant frequency of the piezoelectric resonator 120, e.g. as described herein with reference to FIG. 2, particularly before and/or after processing the calibration assembly 100. The lithium deposition apparatus 300, particularly the transfer chamber 320, may be connected to the testing environment. The lithium deposition apparatus 300 may be configured for transferring the calibration assembly from the transfer chamber 320 to the testing environment. Particularly, the transfer chamber may include an opening for transferring the calibration assembly 100 into the testing environment. According to embodiments, the lithium deposition apparatus 300 may include the testing environment. According to embodiments, the lithium deposition apparatus 300 may include the connector 312 and/or the driver 210.

According to embodiments, as shown in FIG. 3, the testing environment may be an environment outside the lithium deposition apparatus 300, such as a room. According to further embodiments, the testing environment may be a chamber, such as a testing chamber. The testing chamber may be connected to the transfer chamber 320, such that the calibration assembly 100 and/or the piezoelectric resonator 120 may be received by the testing chamber. For example, the testing chamber may be a glove box connected to the transfer chamber 320.

According to embodiments, the testing environment, particularly a testing chamber, may have an inert gas atmosphere at ambient pressure and/or temperature, such as argon gas. The inert gas atmosphere may be a dry atmosphere, such as an atmosphere having a relative humidity below 5 parts per million (ppm), for example approximately 1 ppm, or even below 1 ppm. According to embodiments, the testing environment, particularly a dry room, may have an atmosphere, such as an air atmosphere, with a defined humidity, particularly a dry atmosphere, such as an atmosphere with essentially ambient conditions and a relative humidity below 5%, below 2%, below 1% or even below 0.5%.

According to embodiments, the driver 210 and the connector 312 may both be provided in the testing environment, particularly in embodiments wherein the testing environment is a dry room. According to embodiments, the connector 312 may be provided in the testing environment, and the driver and/or further components connected to the driver, such as a measuring instrument, may be provided outside the testing environment. For example, in embodiments having a testing chamber, the connector 312 may be provided inside the testing chamber, and the driver 210 may be provided outside the testing chamber. A connection between the connector 312 and the driver 210 may be provided through a sealed port, e.g. a sealed port in a wall of the testing chamber.

Connecting the piezoelectric resonator 120 to the driver 210 in the testing environment may beneficially allow determining a resonance frequency of the piezoelectric resonator 120, the resonant frequency being indicative of the thickness of the deposited lithium film. Furthermore, the resonant frequency may be determined over time under the conditions present in the testing environment. A defined environment inside the testing environment may beneficially increase the repeatability of the measurement, and result in comparable measurements even at different timepoints and/or for different samples. Determining the resonant frequency in the testing environment may beneficially allow determining a change in the film thickness, e.g. due to a reaction of the deposited lithium film with a gaseous substance, such as air having a humidity, in the testing environment, the reaction resulting in a change, particularly an increase, in mass of the deposited lithium film. For example, a reaction of water and lithium would result in the formation of lithium hydroxide having a higher molar mass than metallic lithium. The rate of change of the film thickness, i.e. the increase in mass over time, may beneficially allow determining the degree of passivation of the lithium film, as is explained in further detail with reference to FIG. 5.

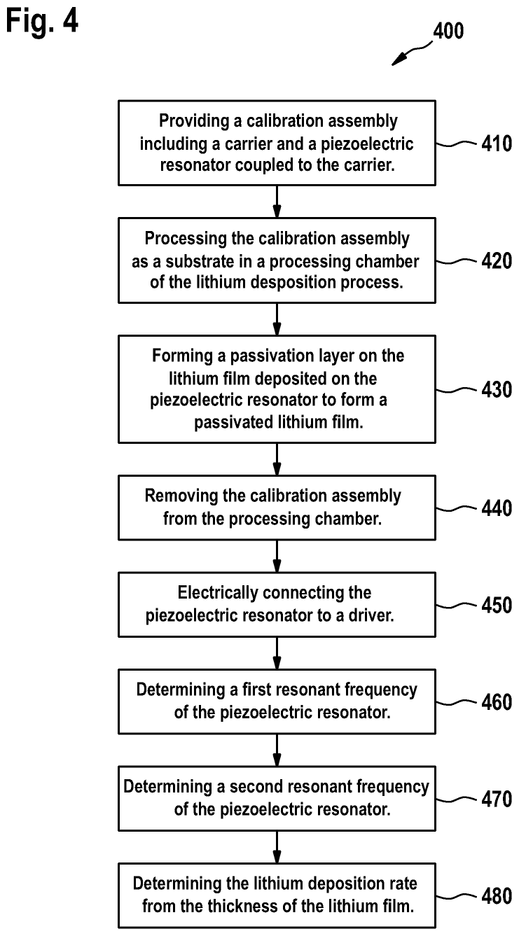

Referring now to FIG. 4, a method 400 of determining a lithium deposition rate in a lithium deposition process is described. The method may be performed e.g. by utilizing a calibration assembly 100 and/or a lithium deposition apparatus 300 according to embodiments described herein.

The method 400 includes providing 410 a calibration assembly including a carrier and a piezoelectric resonator coupled to the carrier. The method 400 further includes processing 420 the calibration assembly as a substrate in a processing chamber of the lithium deposition process. For example, the calibration assembly may be inserted into a substrate carrier instead of a substrate, and/or processed like a substrate, so that lithium is deposited onto the calibration assembly under the same conditions as onto a substrate.

The method 400 may optionally include forming 430 a passivation layer on the lithium film deposited on the piezoelectric resonator to form a passivated lithium film, e.g. a film having a passivation layer similar to a native passivation layer. According to embodiments, forming 430 a passivation layer may include exposing the piezoelectric resonator to the conditions described with respect to embodiments of the transfer chamber 320 described herein. For example, the passivation layer may be formed by exposing the piezoelectric resonator to carbon dioxide included in the atmosphere according to embodiments described herein.

According to embodiments, the piezoelectric resonator may be disconnected from a driver during processing. The piezoelectric resonator may further be disconnected from a driver during the formation of a passivation layer. Disconnecting the driver may beneficially allow the driver to be located outside the processing chamber and/or a chamber for performing a passivation, such as a transfer chamber, and prevent damage to the driver and/or a connector connecting the piezoelectric resonator to the driver during the lithium deposition and/or passivation process.

The method 400 includes removing 440 the calibration assembly from the processing chamber. Removing the calibration assembly from the processing chamber may include transferring the calibration assembly from the processing chamber into a testing environment, such as a testing environment according to embodiments described herein.

The method 400 further includes electrically connecting 450 the piezoelectric resonator to a driver. The driver may be a driver such as the driver 210. Electrically connecting 450 the piezoelectric resonator to a driver may include removing the piezoelectric resonator from the carrier before electrically connecting the piezoelectric resonator to the driver. Electrically connecting 450 the piezoelectric resonator to the driver may include the use of a connector, such as the connector 312, e.g. inserting the piezoelectric resonator into the connector, and/or electrically connecting the piezoelectric resonator to a driver. According to embodiments, the piezoelectric resonator may be removably coupled to the carrier. Accordingly, particularly in embodiments wherein the piezoelectric resonator is removably provided within a calibration assembly, the method may include removably coupling the piezoelectric resonator to the carrier before processing the calibration assembly.

The method 400 further includes determining 460 a resonant frequency of the piezoelectric resonator. The resonant frequency is indicative of a thickness of a lithium film deposited on the piezoelectric resonator in the lithium deposition process. The method 400 may particularly include determining a resonant frequency before processing the calibration assembly, i.e. to obtain the resonant frequency and/or starting frequency of the piezoelectric element before having a lithium layer deposited thereon, and determining a resonant frequency after processing the calibration assembly, i.e. to obtain the resonant frequency and/or final frequency after having a lithium layer deposited thereon. Beneficially, a lithium layer thickness may be determined based on the difference between the starting frequency and the final frequency, e.g. according to the formula described herein. Accordingly, the method may include determining a first resonant frequency of the piezoelectric resonator before processing the calibration assembly, determining a second resonant frequency of the piezoelectric resonator after processing the calibration assembly, determining a resonant frequency difference from the first resonant frequency and the second resonant frequency, and determining the thickness of the lithium film deposited on the piezoelectric resonator in the lithium deposition process from the resonant frequency difference.

According to embodiments, the resonant frequency determined directly after processing the calibration assembly may be a first resonant frequency. The first resonant frequency may be determined in an inert atmosphere. The first resonant frequency may be a frequency of the passivated lithium film, e.g. a lithium film including essentially no further reaction products of the (passivated) lithium film, such as reaction products resulting from a reaction with the lithium film and air having a humidity. The method 400 may further include determining 470 a second resonant frequency. Determining the second resonant frequency may include monitoring a change of the second resonant frequency of the piezoelectric resonator over time. A change of the second resonant frequency over time may be indicative of the chemical stability of the passivated lithium film. Determining the second resonant frequency may include providing the piezoelectric resonator in an environment allowing a chemical reaction between the environment, e.g. a gas and/or vapor present in the environment, such as air having a humidity, and the lithium layer deposited on the piezoelectric resonator. The chemical reaction may result in an increase in the mass of the deposited lithium film, e.g. due to the formation of lithium hydroxide.

According to embodiments, the method 400 may include determining 480 the lithium deposition rate from the thickness of the lithium film. In a first example, based on the determined lithium film thickness, a deposition rate of the process resulting in the measured lithium film thickness can be concluded from the determined lithium film thickness, e.g. the lithium deposition rate of an at least partly unknown deposition process may be determined. In a second example, the lithium film thickness may be correlated with a variable process parameter, such as a lithium evaporation rate, a lithium deposition source temperature, a transfer speed of the calibration assembly through the deposition chamber, and/or a number of passes of the calibration assembly through the deposition chamber. Accordingly, the correlation between the lithium deposition rate and one or more variable parameters may be determined. In a third example, determining the lithium deposition rate may include comparing the measured lithium film layer thickness with an expected lithium film layer thickness, i.e. determining whether the deposition rate is within expected parameters, e.g. by sampling a running process. Accordingly, the method may include adjusting a process parameter of the lithium deposition process according to the determined lithium deposition rate.

Referring now to FIG. 5, determining the chemical stability of a passivation layer according to embodiments is described. The passivation layer may be formed according to embodiments described herein, particularly with respect to the passivation of the lithium film in the transfer chamber 320, and particularly with respect to the passivation 430 described with respect to the method 400.

A method according to embodiments, such as the method 400 described herein, may include forming a passivation layer on the lithium film deposited on the piezoelectric resonator to form a passivated lithium film, and monitoring a change of the resonant frequency of the piezoelectric resonator over time. The change of the resonant frequency is indicative of the chemical stability of the passivated lithium film. The passivation layer may be formed in a transfer chamber of the lithium deposition process, such as the transfer chamber 320. The monitoring of the change of the resonant frequency may include determining at least one, such as several, resonant frequencies of the piezoelectric resonator. Monitoring may be performed in a defined environment. The defined environment may particularly have a defined temperature and a defined humidity, and/or even a defined gas composition. The defined environment may be a testing environment, according to embodiments described herein, such as a dry room and/or a testing chamber.

FIG. 5 shows a typical graph 500 of a change in resonant frequency of a passivated lithium film 520 and a non-passivated lithium film 510. The abscissa corresponds to time t, and the ordinate corresponds to a change in the resonant frequency Δf. In the testing environment, the lithium film reacts with the atmosphere present in the testing environment to form a reaction product having a higher mass than metallic lithium. As can be seen in FIG. 5, the reaction results, over time, in an increase in mass of the lithium film including the reaction products, and a decrease in the resonant frequency f of the piezoelectric element. As shown in FIG. 5, at least in an environment having a relatively low overall reactivity, such as a low humidity dry room, the graph 500 typically shows a zero-order kinetic. Thus, the chemical stability of the passivated lithium film may be determined by comparing the reaction rate df/dt to the reaction rate of the non-passivated lithium film. The determination may, for example, include comparing the change in mass at a certain timepoint (Δf at timepoint t), or include calculating and comparing a slope of each curve 510, 520 (Δf/t). In the example shown in FIG. 5, the piezoelectric resonator having a passivated lithium film deposited thereon shows a decrease of 1 arbitrary unit [AU] of frequency f at timepoint t, while the non-passivated lithium film shows a decrease of 2 [AU]/t. From the rate of decrease, it can be concluded that the passivation of the passivated lithium film resulted in an improved chemical stability, the passivated lithium film being 50% less reactive in the environment present in the defined environment compared to the non-passivated lithium film.

According to embodiments, the result of determining the chemical stability of the passivated lithium film may be utilized for adjusting a process parameter of the passivation process, particularly the forming of a passivation layer, according to the determined chemical stability of the passivated lithium film.

According to embodiments, the calibration assembly may include more than one piezoelectric element. This may, for example, beneficially allow determining a lithium deposition rate at different positions within the lithium deposition chamber or process, e.g. to measure coating uniformity. Beneficial embodiments of calibration assemblies are described in document EP 2 309 220 A1, which is incorporated herein in its entirety, and particularly with regards to the configurations of the thickness measuring devices 10, 20 and 30, as well as aspects related to the transport of the measuring devices through the deposition process, described in the document.

Embodiments of the present disclosure have several advantages including the more accurate measurement of a lithium film thickness, the accurate measurement of a lithium film passivation, and the more accurate monitoring and/or calibration of the lithium-based process obtainable by employing a calibration assembly and/or a method according to embodiments described herein. Furthermore, embodiments described herein are suitable for use under the harsh conditions of a lithium deposition process.

While the foregoing is directed to some embodiments, other and further embodiments may be devised without departing from the basic scope, and the scope is determined by the claims that follow.

1. A calibration assembly for a lithium deposition process, the calibration assembly comprising
a carrier; and a piezoelectric resonator coupled to the carrier,
wherein:
the calibration assembly is configured for being processed in the lithium deposition process, the lithium deposition process including a passivation, the piezoelectric resonator is configured for being electrically connected to a driver for determining a resonant frequency of the piezoelectric resonator,
the resonant frequency is indicative of a thickness of a lithium film deposited on the piezoelectric resonator in the lithium deposition process, and
a change of the resonant frequency over time is indicative of the passivation of the lithium film.

2. The calibration assembly according to claim 1, wherein the piezoelectric resonator comprises an inert metal electrode on a face of the piezoelectric resonator.

3. The calibration assembly according to claim 2, wherein
the inert metal electrode comprises silver metal.

4. The calibration assembly according to claim 1, wherein
the carrier comprises an opening exposing the inert metal electrode to a lithium deposition source of the lithium deposition process for having a lithium film deposited on the inert metal electrode when processed in the lithium deposition process.

5. The calibration assembly according to claim 1, wherein the piezoelectric resonator is removably coupled to the carrier, and wherein the piezoelectric resonator is configured for being removed from the carrier before or after the lithium deposition process.

6. The calibration assembly according to claim 5, wherein the piezoelectric resonator is insertable into a connector of the driver for electrically connecting the piezoelectric resonator to the driver.

7. The calibration assembly according to claim 1, wherein the piezoelectric resonator, when electrically connected to the driver, is a resonator of a microbalance, or a quartz crystal microbalance, and wherein the piezoelectric resonator comprises one selected from the group consisting of: a quartz crystal, an AT-cut quartz crystal or a SC or a RC-cut quartz crystal.

8. The calibration assembly according to claim 1, wherein the calibration assembly is inert when processed in a lithium vapor atmosphere, the lithium vapor atmosphere being generated by evaporating lithium at 500° C. or more under vacuum.

9. A lithium deposition apparatus, comprising:
a calibration assembly, the calibration assembly comprising:
a carrier; and
a piezoelectric resonator coupled to the carrier, wherein:
the calibration assembly is configured for being processed in the lithium deposition process, the lithium deposition process including a passivation,
the piezoelectric resonator is configured for being electrically connected to a driver for determining a resonant frequency of the piezoelectric resonator,
the resonant frequency is indicative of a thickness of a lithium film deposited on the piezoelectric resonator in the lithium deposition process, and
a change of the resonant frequency over time is indicative of the passivation of the lithium film; the lithium deposition apparatus further comprising:
a processing chamber, comprising a lithium evaporation device; and a transfer chamber connected to the processing chamber, wherein the lithium deposition apparatus is configured for:
processing the calibration assembly in the processing chamber,
transferring the calibration assembly from the processing chamber to the transfer chamber,
passivating a lithium film deposited on the calibration assembly during processing in the transfer chamber, and
electrically connecting the piezoelectric resonator to a driver with a connector, the connector being provided in a testing environment.

10. The lithium deposition apparatus according to claim 9, wherein the lithium deposition apparatus comprises the testing environment, the testing environment being connected to the transfer chamber, and wherein the lithium deposition apparatus is configured for transferring the calibration assembly from the transfer chamber to the testing environment.

11. (canceled)

12. A method of determining a lithium deposition rate in a lithium deposition process, the method comprising:
providing a calibration assembly comprising a carrier and a piezoelectric resonator coupled to the carrier;
processing the calibration assembly as a substrate in a processing chamber of the lithium deposition process, wherein the piezoelectric resonator is disconnected from a driver during processing;
removing the calibration assembly from the processing chamber; electrically connecting the piezoelectric resonator to a driver;
determining a resonant frequency of the piezoelectric resonator, wherein the resonant frequency is indicative of a thickness of a lithium film deposited on the piezoelectric resonator in the lithium deposition process; and
determining the lithium deposition rate from the thickness of the lithium film.

13. The method of claim 12, wherein the piezoelectric resonator is removably coupled to the carrier, the method further comprising:
removably coupling the piezoelectric resonator to the carrier before processing the calibration assembly; and
removing the piezoelectric resonator from the carrier before electrically connecting the piezoelectric resonator to the driver.

14. The method according to claim 12, further comprising:
determining a first resonant frequency of the piezoelectric resonator before processing the calibration assembly; determining a second resonant frequency of the piezoelectric resonator after processing the calibration assembly;
determining a resonant frequency difference from the first resonant frequency and the second resonant frequency; and
determining the thickness of the lithium film deposited on the piezoelectric resonator in the lithium deposition process from the resonant frequency difference.

15. The method according to claim 12, further comprising:
adjusting a process parameter of the lithium deposition process according to the determined lithium deposition rate.

16. The method according to claim 12, further comprising:
forming a passivation layer on the lithium film deposited on the piezoelectric resonator to form a passivated lithium film; and
monitoring a change of the resonant frequency of the piezoelectric resonator over time, wherein
the change of the resonant frequency is indicative of the chemical stability of the passivated lithium film.

17. The method according to claim 16, wherein the monitoring is performed in a defined environment, the defined environment having a defined temperature and a defined humidity.

18. The method according to claim 16, wherein the passivation layer is formed in a transfer chamber of the lithium deposition process.

19. A method of characterizing a lithium deposition process, the method comprising:
providing a calibration assembly comprising a carrier and a piezoelectric resonator coupled to the carrier;
processing the calibration assembly as a substrate in a processing chamber of the lithium deposition process;
forming a passivation layer on the lithium film deposited on the piezoelectric resonator to form a passivated lithium film;
removing the calibration assembly from the processing chamber;
electrically connecting the piezoelectric resonator to a driver;
determining a first resonant frequency of the piezoelectric resonator, wherein the first resonant frequency is indicative of a thickness of a lithium film deposited on the piezoelectric resonator in the lithium deposition process;
determining a second resonant frequency, wherein:
determining the second resonant frequency comprises monitoring a change of the second resonant frequency of the piezoelectric resonator over time, and
a change of the second resonant frequency over time is indicative of the chemical stability of the passivated lithium film.

20. The method according to claim 19, wherein the piezoelectric resonator is disconnected from a driver while processing and forming the passivation layer.

21. The method according to claim 19, wherein the second resonant frequency is determined in a defined environment, the defined environment having a defined temperature and a defined humidity.

22. (canceled)
